(19) United States
(12) Patent Application Publication
(10) Pub. No.: US 2007/0139904 A1
(43) Pub. Date: Jun. 21, 2007

(54) Low-profile assemblies for providing board level EMI shielding for electrical components on opposite sides of printed circuit boards

(76) Inventors: Gerald Robert English, Glen Ellyn, IL (US); Allan Richard Zuehlsdorf, Sycamore, IL (US)

Correspondence Address: Anthony G. Fussner, Suite 400, 7700 Bonhomme, St. Louis, MO, 63105, US

(21) Appl. No.: 11/514,071

(22) Filed: Aug. 31, 2006

Related U.S. Application Data
(63) Continuation-in-part of application No. 29/244,955, filed on Dec. 16, 2005.
(63) Continuation-in-part of application No. 29/244,956, filed on Dec. 16, 2005.
(63) Continuation-in-part of application No. 29/244,957, filed on Dec. 16, 2005.

(51) Int. Cl. H05K 9/00

(52) U.S. Cl. 361/818

(57) ABSTRACT

An EMI shielding assembly generally includes a frame attachable to the board's first side, and first and second covers configured to be respectively positioned on generally opposite sides of the board. The first cover is configured to cover at least one opening along an upper portion of the frame. The second cover is attachable to the first cover with the first and second covers respectively positioned along the board's generally opposite first and second sides. Accordingly, the assembly is operable for shielding one or more electrical components on the board's first side that are within a first interior defined by the frame's walls, first cover, and at least a portion of the board's first side, and one or more electrical components on the board's second side that are within a second interior defined by the second cover and at least a portion of the board's second side.

### CROSS-REFERENCE TO RELATED APPLICATIONS

This application is a continuation-in-part of U.S. patent application Ser. No. 29/244,955 filed Dec. 16, 2005.

This application is a continuation-in-part of U.S. patent application Ser. No. 29/244,956 filed Dec. 16, 2005.

This application is a continuation-in-part of U.S. patent application Ser. No. 29/244,957 filed Dec. 16, 2005.

The disclosures of the above applications are incorporated herein by reference.

### FIELD

The present disclosure generally relates to multi-piece shielding assemblies for shielding components of a printed circuit board from electromagnetic interference (EMI)/radio frequency interference (RFI).

### BACKGROUND

The statements in this section merely provide background information related to the present disclosure and may not constitute prior art.

Electronic equipment typically includes electrical components and circuits mounted on a substrate that can be sensitive to electromagnetic interference (EMI) and radio frequency interference (RFI). Such EMI/RFI interference may originate from internal sources within the electronic equipment or from external EMI/RFI interference sources. Interference can cause degradation or complete loss of important signals, thereby rendering the electronic equipment inefficient or inoperable. Accordingly, the circuits (sometimes referred to as RF modules or transceiver circuits) usually require EMI/RFI shielding in order to function properly. Such shielding reduces interference not only from external sources, but also from various functional blocks within the module.

As used herein, the term “EMI” should be considered to generally include and refer to EMI emissions and RFI emissions, and the term “electromagnetic” should be considered to generally include and refer to electromagnetic and radio frequency from external sources and internal sources. Accordingly, the term shielding (as used herein) generally includes and refers to EMI shielding and RFI shielding, for example, to prevent (or at least reduce) ingress and egress of EMI and RFI relative to a housing or other enclosure in which electronic equipment is disposed.

By way of example, electronic circuits or components of a printed circuit board (PCB) are often enclosed with shields to localize EMI within its source, and to insulate other devices proximal to the EMI source. Such shields may be soldered or otherwise affixed to the PCB, thus increasing the overall size of the PCB. Soldered shields, however, may need to be removed to repair or replace a covered component, which can be an expensive and time-consuming task that can even cause damage to the PCB.

### SUMMARY

According to various aspects, exemplary embodiments are provided of assemblies operable for providing EMI shielding for electrical components on generally opposite first and second sides of a board. In one exemplary embodiment, the assembly generally includes a frame attachable to the board's first side, and first and second covers configured to be positioned on generally opposite sides of the board. The frame includes walls and at least one opening along an upper portion of the frame. The frame's walls are configured to be disposed generally about one or more electrical components on the board's first side. The first cover is configured to cover the at least one opening of the frame. The second cover is attachable to the first cover with the first and second covers respectively positioned along the board's generally opposite first and second sides. Accordingly, the assembly is operable for shielding one or more electrical components on the board's first side that are within a first interior defined by the frame's walls, first cover, and at least a portion of the board's first side, and one or more electrical components on the board's second side that are within a second interior defined by the second cover and at least a portion of the board's second side.

Another embodiment includes a low-profile assembly capable of providing board-level EMI shielding for electrical components on generally opposite first and second sides of a board. In this embodiment, the assembly generally includes a frame attachable to the board's first side. The frame includes walls and at least one opening along an upper portion of the frame. The frame's walls are configured to be disposed generally about one or more electrical components on the board's first side. The assembly also includes a first cover having a lid portion to cover the at least one opening of the frame. The first cover has wall portions downwardly depending relative to the lid portion. The wall portions have sufficient length for extending across a thickness defined between the board's first and second sides to thereby allow positioning of the end portions of the first cover's wall portions on a side of the board opposite that of the lid portion. The assembly further includes a second cover. At least one of the first and/or second covers includes one or more protrusions for interlocking engagement with corresponding openings of the other one of the first and/or second covers to thereby attach the second cover to the first cover. This interlocking engagement can also help retain the relative positioning of the first cover generally over the frame with the lid portion covering the at least one opening of the frame. Accordingly, the assembly is operable for shielding one or more electrical components on the board's first side that are within a first interior defined by the frame's walls, first cover, and at least a portion of the board's first side, and one or more electrical components on the board's second side that are within a second interior defined by the second cover and at least a portion of the board's second side.

Additional aspects relate to methods of using EMI shielding assemblies. One particular embodiment includes a method of providing EMI shielding for electrical components on generally opposite first and second sides of a board. The method generally includes positioning a first cover relative to a frame such that one or more electrical components on the board's first side are within a first interior defined by the frame, first cover, and at least a portion of the board's first side. The method also includes attaching a second cover to the first cover such that the first and second covers are respectively positioned along the board's generally opposite first and second sides, and such that one or more electrical components on the board's second side are within a second interior defined by the second cover and at least a portion of the board's second side.

Further aspects and features of the present disclosure will become apparent from the detailed description provided hereinafter. In addition, any one or more aspects of the present disclosure may be implemented individually or in any combination with any one or more of the other aspects of the present disclosure. It should be understood that the detailed description and specific examples, while indicating exemplary embodiments of the present disclosure, are intended for purposes of illustration only and are not intended to limit the scope of the present disclosure.

### DRAWINGS

The drawings described herein are for illustration purposes only and are not intended to limit the scope of the present disclosure in any way.

FIG. 1 is an exploded perspective view of an exemplary EMI shielding assembly that includes first and second covers, and a frame, and illustrating the frame mounted to an exemplary printed circuit board, and the first and second covers positioned on opposite sides of the printed circuit board according to exemplary embodiments;

FIG. 2 is a lower exploded perspective view of the EMI shielding assembly and printed circuit board shown in FIG. 1;

FIG. 3 is a perspective view of the EMI shielding assembly and printed circuit board shown in FIG. 1 after the EMI shielding assembly has been assembled with the first and second covers disposed on generally opposite sides of the printed circuit board;

FIG. 4 is a lower perspective view of the EMI shielding assembly and printed circuit board shown in FIG. 3;

FIG. 5 is a front elevation view of the EMI shielding assembly and printed circuit board shown in FIG. 3;

FIG. 6 is a right side elevation view of the EMI shielding assembly and printed circuit board shown in FIG. 5;

FIG. 7 is a cross-sectional view of the EMI shielding assembly and printed circuit board taken along the line 7-7 in FIG. 6; and

FIG. 8 is a cross-sectional view of the EMI shielding assembly and printed circuit board taken along the line 8-8 in FIG. 5.

### DETAILED DESCRIPTION

The following description is merely exemplary in nature and is in no way intended to limit the present disclosure, application, or uses. It should be understood that throughout the drawings, corresponding reference numerals indicate like or corresponding parts and features.

Various embodiments are disclosed of shielding assemblies capable of providing EMI shielding for electrical components on both sides of a printed circuit board. In some embodiments, a shielding assembly includes a frame adapted to be secured to a board, and first and second covers that are configured to be positioned on generally opposite sides of the board. To install or assemble such a dual-sided shielding assembly, the frame is placed (e.g., using pick-and-place equipment, etc.) on a first side of a printed circuit board (e.g., PCMCIA-type wireless card, etc.). The frame can then be mounted to the first side of the board, such as via an exemplary surface mounting process (e.g., soldering, solder reflowing, etc.). The first and second covers can then be respectively positioned on or adjacent the generally opposite first and second sides of the board. The first cover and second cover can then be attached to each other, such that the first and second covers are respectively positioned along the board's generally opposite first and second sides. The attachment of the first and second covers can also retain the relative positioning of the first cover generally over the frame. Additionally, or alternatively, other means may be provided for attachment of the frame and the first cover. The attachment of the second cover to the first cover can be accomplished in various ways, such as by an interlocking engagement of one or more protuberances (e.g., catches, snaps, latches, tabs, detents, protuberances, protrusions, ribs, ridges, ramp-ups, darts, lances, dimples, half-dimples, combinations thereof, etc.) with one or more retaining openings (e.g., recesses, voids, cavities, slots, grooves, holes, depressions, combinations thereof, etc.). In some embodiments, the first cover includes tabs that extend from the first side through to the second side. The tabs have end portions with protrusions for interlocking engagement with corresponding openings of the second cover. The first and/or second cover can be made from sheet metal. Alternatively, other suitable materials can be used. In some embodiments, a plurality of interior EMI shielding compartments may be formed within the first interior defined by the frame, first cover, and at least a portion of the board's first side, and/or within a second interior defined by the second cover and at least a portion of the board's second side. One or more other components may also be disposed along (e.g., overmolded, molded to, attached, etc.) an interior portion of the first and/or second covers, such as resilient partitioning members or partitioning ribs, electrically-conductive elastomer, thermal interface materials (e.g., thermally-conductive compliant material, etc.), etc. In some embodiments, one or more resilient or flexible members (e.g., electrically-conductive elastomeric members or components, etc.) are disposed (e.g., overmolded onto, adhesively bonded, welded, etc.) on an inner surface of the first and/or second cover. The resilient or flexible members can establish contact and electrical conductivity with at least one electrically-conductive surface (e.g., grounding traces, etc.) on the corresponding first and/or second side of the board or substrate.

According to various aspects, exemplary embodiments are provided of assemblies operable for providing EMI shielding for electrical components on generally opposite first and second sides of a board. In one exemplary embodiment, the assembly generally includes a frame attachable to the board's first side, and first and second covers configured to be positioned on generally opposite sides of the board. The frame includes walls and at least one opening along an upper portion of the frame. The frame's walls are configured to be disposed generally about one or more electrical components on the board's first side. The first cover is configured to cover the at least one opening of the frame. The second cover is attachable to the first cover with the first and second covers respectively positioned along the board's generally opposite first and second sides. Accordingly, the assembly is operable for shielding one or more electrical components on the board's first side that are within a first interior defined by the frame's walls, first cover, and at least a portion of the board's first side, and one or more electrical components on the board's second side that are within a second interior defined by the second cover and at least a portion of the board's second side.

Another embodiment includes a low-profile assembly capable of providing board-level EMI shielding for electrical components on generally opposite first and second sides of a board. In this embodiment, the assembly generally includes a frame attachable to the board's first side. The frame includes walls and at least one opening along an upper portion of the frame. The frame's walls are configured to be disposed generally about one or more electrical components on the board's first side. The assembly also includes a first cover having a lid portion to cover the at least one opening of the frame. The first cover has wall portions downwardly depending relative to the lid portion. The wall portions have sufficient length for extending across a thickness defined between the board's first and second sides to thereby allow positioning of the end portions of the first cover's wall portions on a side of the board opposite that of the lid portion. The assembly further includes a second cover. At least one of the first and/or second covers includes one or more protrusions for interlocking engagement with corresponding openings of the other one of the first and/or second covers to thereby attach the second cover to the first cover. This interlocking engagement can also help retain the relative positioning of the first cover generally over the frame with the lid portion covering the at least one opening of the frame. Accordingly, the assembly is operable for shielding one or more electrical components on the board's first side that are within a first interior defined by the frame's walls, first cover, and at least a portion of the board's first side, and one or more electrical components on the board's second side that are within a second interior defined by the second cover and at least a portion of the board's second side.

Additional aspects relate to methods of using EMI shielding assemblies. One particular embodiment includes a method of providing EMI shielding for electrical components on generally opposite first and second sides of a board. The method generally includes positioning a first cover relative to a frame such that one or more electrical components on the board's first side are within a first interior defined by the frame, first cover, and at least a portion of the board's first side. The method also includes attaching a second cover to the first cover such that the first and second covers are respectively positioned along the board's generally opposite first and second sides, and such that one or more electrical components on the board's second side are within a second interior defined by the second cover and at least a portion of the board's second side.

Accordingly, some embodiments can provide shielding assemblies that are low profile and/or with a reduced height or reduce shielding envelope. Some embodiments can also provide dual-sided board component access and reduce part count, for example, by using only one frame in some embodiments.

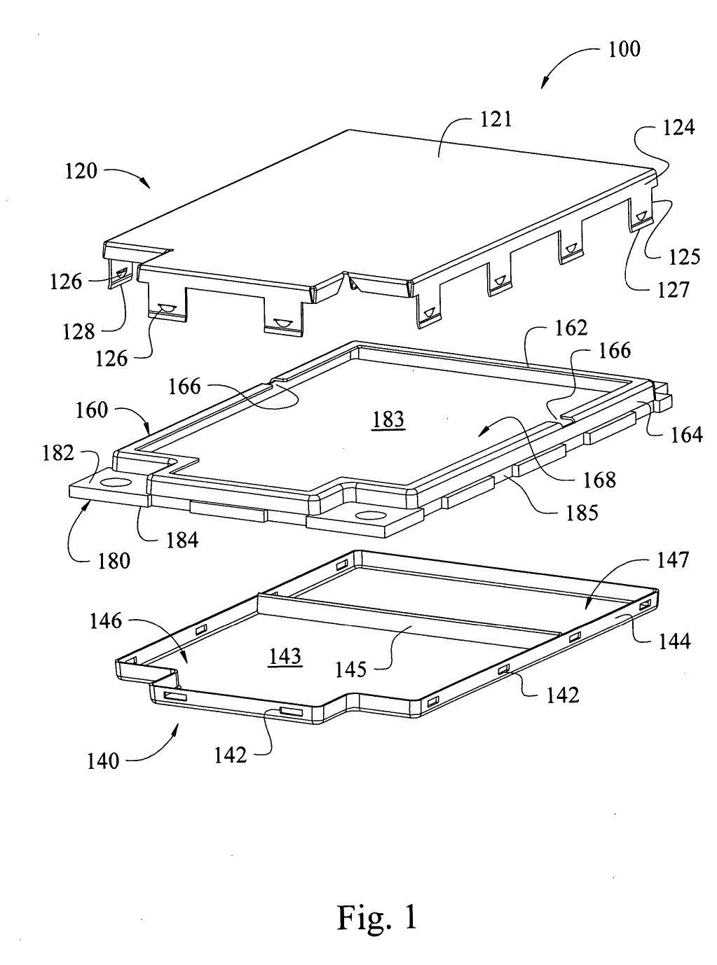

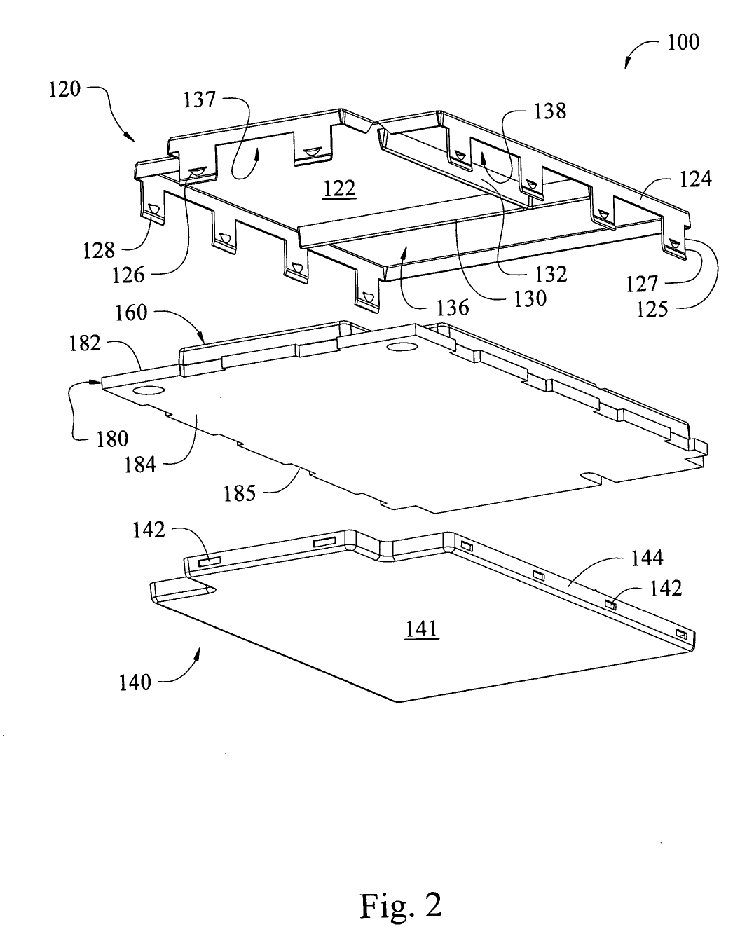

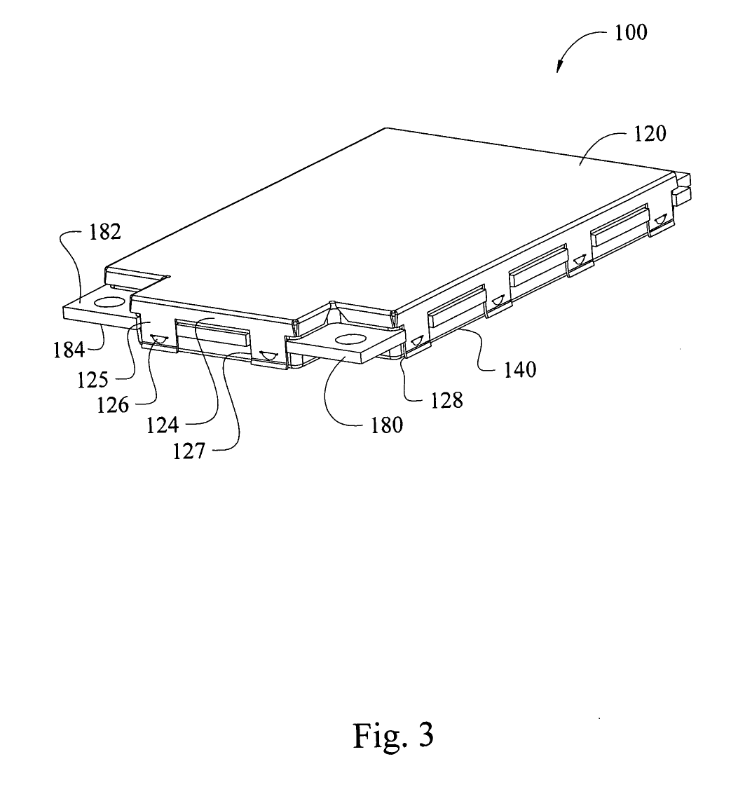

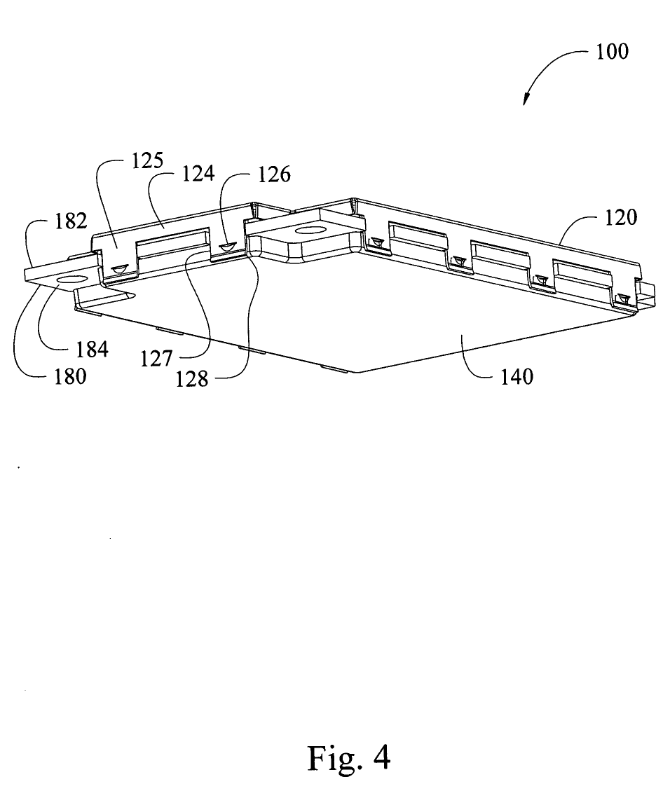

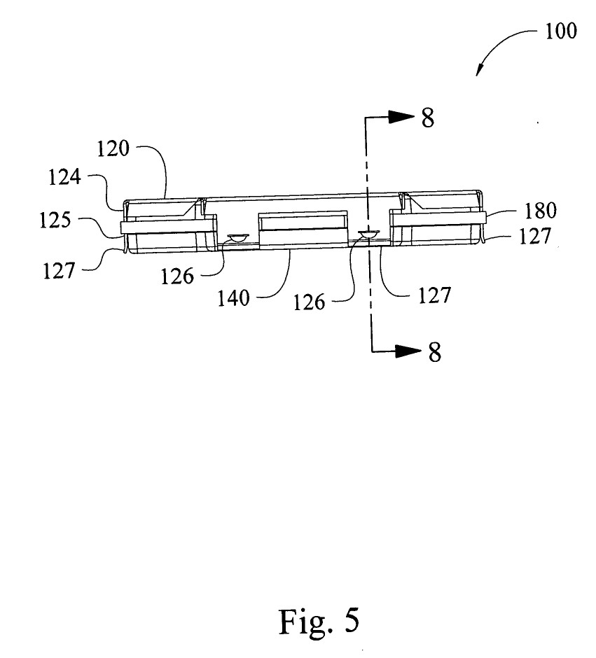

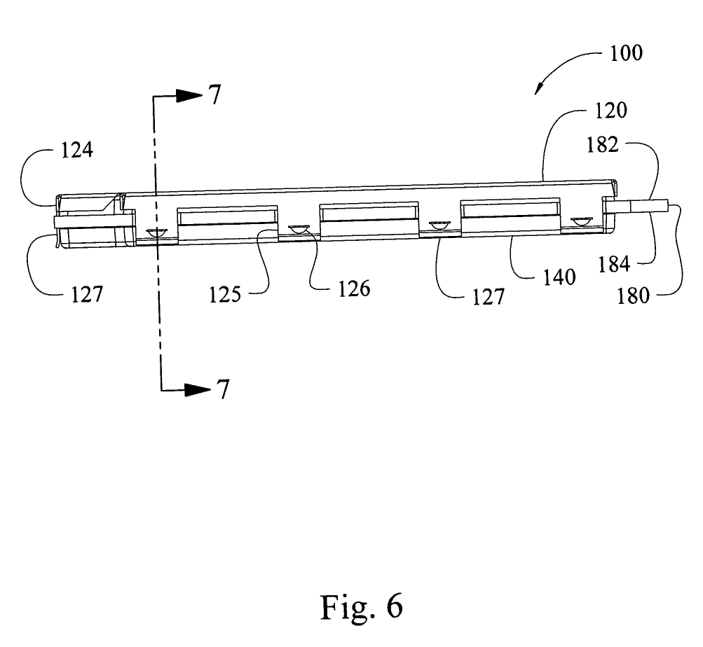

FIGS. 1 and 2 are exploded views of an exemplary EMI shielding assembly 100 embodying one or more aspects of the present disclosure. As shown, the assembly 100 generally includes a first cover 120, a second cover 140, and a base member or frame 160. As shown in FIGS. 3 through 8, the frame 160 can be surface mounted (e.g., soldered, etc.) to a first side 182 of a board 180. The first and second covers 120, 140 can be respectively positioned along, adjacent or on generally opposite sides 182 and 184 of the board 180. The first and second covers 120, 140 can be attached to each other. When assembled or installed as shown in FIGS. 3 through 8, the shielding assembly 100 is operable for providing EMI shielding for electrical components on the board's first side 182 that are within a first interior defined by the frame 160, first cover 120, and portion 183 (FIG. 1) of the board's first side 182. The shielding assembly 100 is also operable for providing EMI shielding for electrical components on the board's second side 184 that are within a second interior defined by the second cover 140 and the board's second side 184.

The assembly 100 is capable of shielding electronic component(s) from EMI/RFI emitted from other electronic components, and/or inhibiting EMI/RFI emitted by the electronic component(s) from interfering with other components. The assembly 100 can be used with a wide range of electronic components and packages, such as integrated circuits mounted on a printed circuit board, etc.

With continued reference to FIG. 1, the frame 160 will now be described in more detail. As shown in FIG. 1, the frame 160 includes a perimeter rim 162, walls 164, and an opening or window 168. The walls 164 are configured to be secured to a printed circuit board (or other substrate). By way of example, the opening or window 168 may provide access to one or more electronic components on the board's first side 182, after the first cover 120 has been detached from the second cover 140 and removed from the frame 160.

With further reference to FIG. 1, the frame 160 can also include notched or cutout portions 166. These notches or cutouts 166 can be configured (e.g., positioned, dimensionally sized, shaped, etc.) to provide sufficient clearance such that an elastomeric member 130 (FIG. 2) does not interfere with the frame 160. For example, the notches or cutouts 166 can provide clearance such that the first cover's elastomeric member 130 doesn't contact the frame 160 as the first cover 120 is being disposed generally over the frame 160, where that contact might otherwise inhibit installation. Some exemplary embodiments are configured such that there is a clearance of about 0.15 millimeters between the frame 160 and the elastomeric member 130. Alternatively, other embodiments may include a larger clearance or a smaller clearance.

In various embodiments, the frame 160 can be integrally or monolithically formed as a single component. In one particular embodiment, the frame 160 can be formed by stamping a flat profile pattern in a piece of material for the frame 160. The stamped profile for the frame 160 can include the opening 168 and the notches or cutouts 166. After stamping the flat pattern profile for the frame 160 into the piece of material, the walls 164 may then be folded or bent generally perpendicular as shown in FIGS. 1 and 2. Even though the frame 160 can be formed integrally, such is not required for all embodiments. For example, other embodiments of the frame may include wall portions that are discrete components separately attached to the frame, for example, by welding, adhesives, among other suitable methods. Alternative configurations (e.g., shapes, sizes, etc.), materials, and manufacturing methods (e.g., drawing, etc.) can be used for making the frame 160.

A wide range of materials can be used for the frame 160, such as nickel-silver alloys, copper-nickel alloys, cold rolled steel, stainless steel, tin-plated cold rolled steel, tin-plated copper alloys, carbon steel, brass, copper, aluminum, copper-beryllium alloys, phosphor bronze, steel, combinations thereof, among other suitable electrically-conductive and/or non-magnetic materials. In one exemplary embodiment, a frame 160 is formed from a sheet of nickel silver alloy having a thickness of about 0.20 millimeter. The materials and dimensions provided herein are for purposes of illustration only, as the assembly and components thereof can be configured from different materials and/or with different dimensions depending, for example, on the particular application, such as the component to be shielded, space considerations within the overall apparatus, EMI shielding and heat dissipation needs, and other factors.

As shown in FIG. 1, the first cover 120 includes a generally flat planar lid portion 121 and perimeter wall portions 124. The lid portion 121 is configured so as to substantially cover the entire opening 168 of the frame 160, when the first cover 120 is disposed generally over the frame 160 (as shown in FIGS. 3 through 8).

The first cover 120 also includes tabs or wall portions 125 downwardly depending relative to the lid portion 121. As shown in FIGS. 3 through 8, the tabs 125 have sufficient length for extending across a thickness defined between the board's first and second sides 182 and 184, to thereby allow positioning of the end portions 127 of the first cover's tabs 125 on a side 184 of the board 180 opposite that of the first cover's lid portion 121. As shown in FIGS. 3 through 8, the first cover's lid portion 121 and tab end portions 127 can be respectively positioned on opposite sides 182 and 184 of the board 180.

As shown in FIGS. 3 through 8, the end portions 127 of the tabs 125 are configured for positioning through openings 185 (e.g., holes, notches, cutout portions, etc.) in the board 180. In FIGS. 1 and 2, the board 180 is shown with generally rectangular notches or cutouts 185 along a periphery of the board 180. Alternatively, the assembly 100 can also be used with other boards having openings with different configurations (e.g., through-holes, semi-circular notches, etc.).

The tab end portions 127 may also be bent or curved so as define camming surfaces 128. During installation of the assembly 100, contact between the camming surfaces 128 and frame 160 and/or board 180 can urge the tabs 125 generally outwardly. Accordingly, this camming feature can thus facilitate the positioning of the tab end portions 127 through the corresponding notches 185 of the board 180 and subsequent engagement of the first cover's protuberances 126 within the second cover's openings 142.

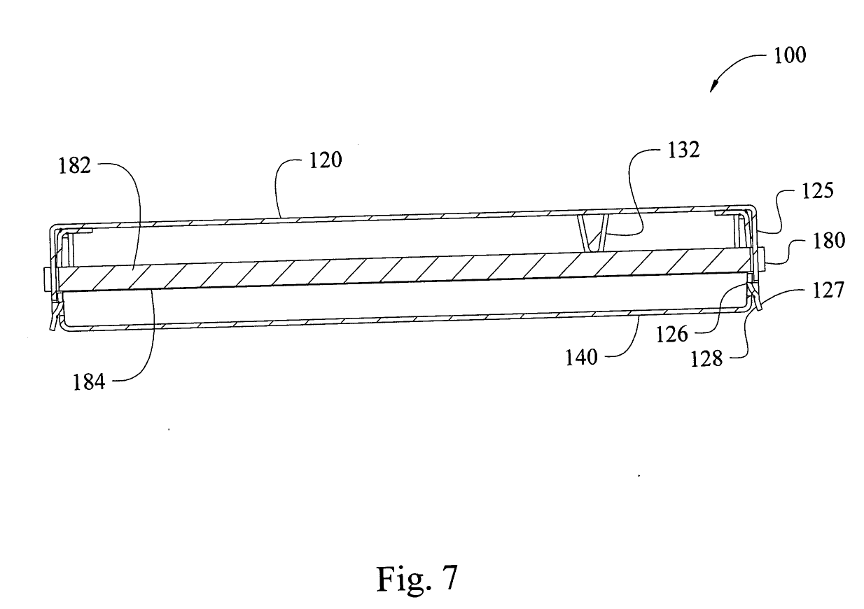

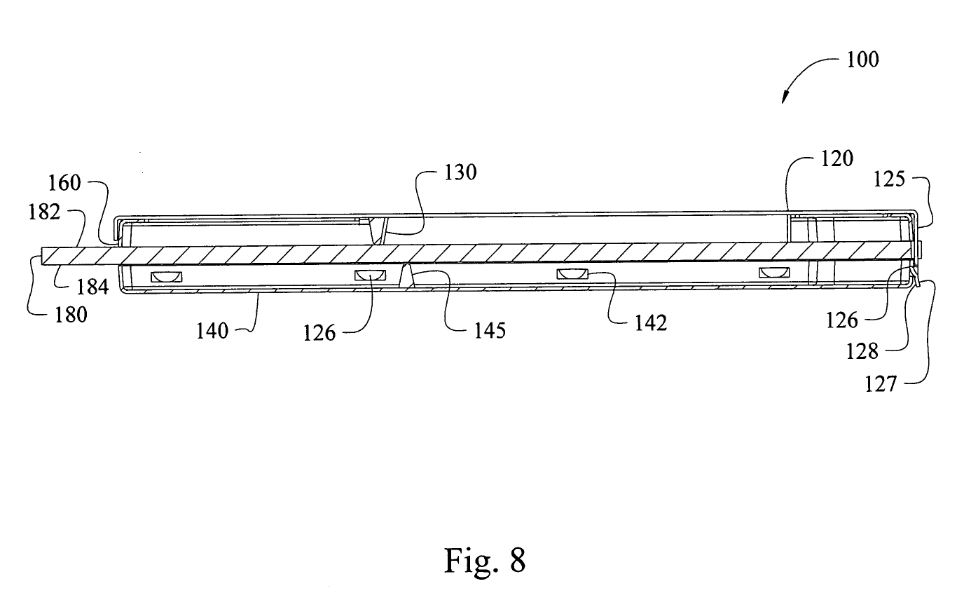

The first cover's tabs 125 include protuberances 126 configured to be retained by corresponding openings 142 of the second cover 140. In the particular embodiment shown in FIGS. 1 and 2, the protuberances 126 comprise inwardly extending half-dimples. As shown in FIGS. 7 and 8, the upper surfaces of the half-dimples are configured to interlock generally underneath the upper surface of the second cover's openings 142.

With further reference to FIGS. 1 and 2, the lower portions of the half-dimples can also function or operate as camming surfaces. During the installation process, contact between the rounded lower portion of the inwardly extending half-dimples and the frame 160 and/or board 180 can urge the tabs 125 generally outwardly. Accordingly, this camming feature can thus facilitate the positioning of the tab end portions 127 through the corresponding notches 185 of the board 180 and subsequent engagement of the first cover's protuberances 126 within the second cover's openings 142.

Alternatively, the first cover 120 can include other suitable locking means besides the half-dimple protuberances, such as catches, snaps, latches, tabs, detents, protrusions, ribs, ridges, ramp-ups, darts, lances, dimples, half-dimples, combinations thereof, etc. In yet other alternative embodiments, the first cover 120 may comprise one or more retaining openings (e.g., recesses, voids, cavities, slots, grooves, holes, depressions, combinations thereof, etc.) configured to engagingly receive one or more protuberances (e.g., catches, snaps, latches, tabs, detents, protuberances, protrusions, ribs, ridges, ramp-ups, darts, lances, dimples, half-dimples, combinations thereof, etc.) of the second cover 140. In still other embodiments, the first cover 120 may include both retaining apertures and protuberances. Alternatively, other means can be employed for attaching the first cover to the second cover besides the interlocking engagement of protuberances within openings.

In various embodiments, the first cover 120 can be integrally or monolithically formed as a single component. In this particular embodiment, the first cover 120 can be formed by stamping in a piece of material a flat profile pattern for the first cover 120. The stamped profile for the first cover 120 includes the protuberances 126 (e.g., inwardly extending half-dimples and detents defined thereby, etc.), the wall portions 124, and tabs 125. After stamping the flat pattern profile for the first cover 120 into the piece of material, the wall portions 124 may then be folded or bent generally perpendicular as shown in FIG. 1 and 2. Even though the first cover 120 can be formed integrally, such is not required for all embodiments. For example, other embodiments may include tabs, wall portions, and/or protuberances that are discrete components separately attached to the first cover 120, for example, by welding, adhesives, among other suitable methods. Alternative configurations (e.g., shapes, sizes, etc.), materials, and manufacturing methods (e.g., drawing, etc.) can be used for making the first cover 120.

A wide range of materials can be used for the first cover 120, such as nickel-silver alloys, copper-nickel alloys, cold rolled steel, stainless steel, tin-plated cold rolled steel, tin-plated copper alloys, carbon steel, brass, copper, aluminum, copper-beryllium alloys, phosphor bronze, steel, combinations thereof, among other suitable electrically-conductive and/or non-magnetic materials. In one exemplary embodiment, the first cover 120 is formed from a sheet of nickel silver alloy having a thickness of about 0.13 millimeter. The materials and dimensions provided herein are for purposes of illustration only, as the assembly and components thereof can be configured from different materials and/or with different dimensions depending, for example, on the particular application, such as the component to be shielded, space considerations within the overall apparatus, EMI shielding and heat dissipation needs, and other factors.

As shown in FIG. 2, resilient flexible rib members 130 and 132 are disposed on a portion of the inner surface 122 of the first cover's lid portion 121. In some embodiments, the flexible rib members 130 and/or 132 are configured (e.g., dimensioned, shaped, positioned etc.) to have a height greater than the distance between the board's first side 182 and the first cover's inner surface 122 when the assembly 100 is installed as shown in FIGS. 3 through 8. This relative sizing can thus allow for at least some compression of the flexible rib members 130 and/or 132. In some embodiments, the flexible members 130 and/or 132 are electrically-conductive. In such embodiments, the compression of the flexible members 130 and/or 132 can preferably produce sufficient contact pressure effective for establishing at least a certain level (e.g., minimal level in some embodiments, etc.) of electrical conductivity between at least one conductive surface (e.g., grounding traces, etc.) on the board 180 and the first cover 120 via the flexible members 130 and/or 132.

The first cover 120 and flexible rib members 130 and/or 132 cooperatively define or form partitioned EMI shielding areas, enclosures, or compartments. When the assembly 100 is installed, the flexible or elastomer rib members 130 and/or 132 may intervene between one or more areas on a circuit board to partition one or more areas from other areas. The elastomer rib members 130 and/or 132 can provide for an attenuation of transfer of electromagnetic (EMI) energy among each of the one or more partitioned areas.

In the particular illustrated embodiment, the rib members 130 and 132 are generally perpendicular to each other, such that there are three EMI shielding compartments 136,137, and 138. Accordingly, the ribs 130, 132 and first cover 120 can thus provide partitioned areas defined by the assembly 100 that provide EMI shielding of one or more electrical components located within each partitioned area. Alternative embodiments can include more or less rib members in other configurations (e.g., shapes, sizes, materials, orientation, etc.) for defining more or less EMI shielding compartments. In yet other embodiments, the first cover does not include any of such rib members.

As shown in FIGS. 7 and 8, the rib members 130 and 132 are configured with a cross-section that reduces in width from a base portion (adjacent the first cover lid portion 121) towards a free end portion. Alternative configurations can also be employed.

In some embodiments, the elastomer rib members 130 and/or 132 may comprise electrically-conductive material disposed on the exterior surface of the elastomer member. In such embodiments, the electrically-conductive elastomeric rib members 130 and/or 132 can be disposed or affixed on the inner surface 122 of the first cover's lid portion 121 by an adhesive (or other suitable attachment means) that bonds the electrically-conductive elastomeric member 130 and/or 132 to the first cover 120. The elastomer members 130 and/or 132 may be dispensed onto (e.g., via form-in-place dispensing equipment, hand-held dispenser or caulk gun, etc.), molded onto (e.g., overmolded, etc.) or attached (e.g., adhesively attached, etc.) to various portions of the first cover 120. By way of example only, various embodiments include electrically-conductive elastomer dispensed onto the first cover 120. Other embodiments include electrically-conductive elastomer over-molded onto the first cover 120 through an insert-molding process.

The electrically-conductive elastomeric rib members 130, 132 can be formed from various materials. In some preferred embodiments, the rib members 130, 132 are formed from elastomeric materials filled with electrically-conductive particles. Examples of preferred elastomeric materials include silicone, fluorosilicone, fluorocarbon, and Ethylene Propylene Diene Monomer [EPDM]. Thermoplastic elastomer can also be used as the elastomeric material. Examples of preferred electrically-conductive particles include silver coated glass particles, which can be used to make an elastomeric material electrically-conductive. In other embodiments, silver particles, silver coated copper particles, silver coated aluminum particles, silver plated nickel particles, nickel coated graphite particles, and graphite particles can also be used to make the elastomeric material electrically-conductive.

The electrically-conductive elastomer rib members 130 and 132 may be arranged in any number of configurations, and may be formed integrally or separately from each other. For example, the elastomer rib member 130 may comprise a separate rib portion that meets or converges at an intersection point with the elastomer rib portion 132.

In some embodiments, the elastomer rib members 130 and/or 132 can be thermally conductive (e.g., have a thermal conductivity coefficient greater than that of air alone, etc.) for creating a thermally-conducting heat path from the assembly 100 to the board 180. In such embodiments, the elastomer rib members 130 and/or 132 can be configured to contact at least one electrically-conductive surface on the first side 182 of the board 180 from which to conduct heat, such as a grounding trace or a board-mounted electrical component. With this contact, the elastomer rib members 130 and/or 132 can facilitate transferring and/or thermally conducting of heat from the at least one electrically-conductive surface to the first cover 120.

Some embodiments include a thermal interface material disposed on an interior portion of the first cover 120 and/or second cover 140 for forming a thermally-conducting heat path from one or more electrical components of the board to the assembly. This thermal interface material may comprise the elastomeric rib members 130 and/or 132 in some embodiments, or the thermal interface material may be in addition to, or as an alternative to, the elastomeric rib members 130 and/or 132 on other embodiments. In either case, a wide variety of materials can be used for a thermal interface, which are preferably better thermal conductors and have higher thermal conductivities than air alone. Accordingly, the thermal interface (with its compressive contact against the electrical component) can thus allow for improved heat transfer from the electrical component to the first cover 120 as compared to those designs relying solely upon air to define the heat path between the electrical component and the underside of the cover. Some preferred embodiments include a thermal interface formed from T-fleX™ 600 series thermal gap filler material commercially available from Laird Technologies, Inc. of Saint Louis, Missouri. In one particular preferred embodiment, a thermal interface comprises T-flex™ 620 thermal gap filer material, which generally includes reinforced boron nitride filled silicone elastomer. By way of further example, other embodiments include thermal interfaces molded from electrically-conductive elastomer. Additional exemplary embodiments include thermal interface materials formed from ceramic particles, ferrite EMI/RFI absorbing particles, metal or fiberglass meshes in a base of rubber, gel, grease or wax, etc. Other suitable thermal interface materials are set forth in the table below. Alternative embodiments, however, can provide an assembly that does not include any such thermal interfaces.

With reference to FIGS. 1 and 2, the second cover 140 includes a generally flat planar portion 141 and perimeter wall portions 144 having openings 142.

The openings 142 are configured for engagingly receiving the first cover's protuberances 126, as shown in FIGS. 3 through 8.

In the particular embodiment shown in FIGS. 1 and 2, the second cover's openings 142 are generally rectangular. Alternatively, the second cover 140 can include other suitable openings having other configurations (e.g., shapes, sizes, locations, etc.) than what is shown in the figures, and/or other types of openings (e.g., recesses, voids, cavities, slots, grooves, holes, depressions, combinations thereof, etc.) In other embodiments, the second cover 140 may include one or more protuberances (e.g., catches, snaps, latches, tabs, detents, protuberances, protrusions, ribs, ridges, ramp-ups, darts, lances, dimples, half-dimples, combinations thereof, etc.) configured to be interlockingly engaged with corresponding openings of the first cover 120. In still other embodiments, the second cover 140 may include both retaining apertures and protuberances. Alternatively, other means can be employed for attaching the first cover to the second cover besides the interlocking engagement of protuberances within openings.

In various embodiments, the second cover 140 can be integrally or monolithically formed as a single component. In this particular embodiment, the second cover 140 can be formed by stamping in a piece of material a flat profile pattern for the second cover 140. The stamped profile for the second cover 140 includes the openings 142 and wall portions 144. After stamping the flat pattern profile for the second cover 140 into the piece of material, the wall portions 144 may then be folded or bent generally perpendicular as shown in FIG. 1 and 2. Even though the second cover 140 can be formed integrally, such is not required for all embodiments. For example, other embodiments may include openings, wall portions, and/or protuberances that are discrete components separately attached to the second cover 140, for example, by welding, adhesives, among other suitable methods. Alternative configurations (e.g., shapes, sizes, etc.), materials, and manufacturing methods (e.g., drawing, etc.) can be used for making the second cover 140.

A wide range of materials can be used for the second cover 140, such as nickel-silver alloys, copper-nickel alloys, cold rolled steel, stainless steel, tin-plated cold rolled steel, tin-plated copper alloys, carbon steel, brass, copper, aluminum, copper-beryllium alloys, phosphor bronze, steel, combinations thereof, among other suitable electrically-conductive and/or non-magnetic materials. In one exemplary embodiment, the second cover 140 is formed from a sheet of nickel silver alloy having a thickness of about 0.13 millimeter. The materials and dimensions provided herein are for purposes of illustration only, as the assembly and components thereof can be configured from different materials and/or with different dimensions depending, for example, on the particular application, such as the component to be shielded, space considerations within the overall apparatus, EMI shielding and heat dissipation needs, and other factors.

As shown in FIG. 2, at least one resilient flexible rib member 145 is disposed on a portion of an inner surface 143 of the second cover 140. In some embodiments, the flexible rib member 145 is configured (e.g., dimensioned, shaped, positioned etc.) to have a height greater than the distance between the board's second side 184 and the second cover's inner surface 143 when the assembly 100 is installed as shown in FIGS. 3 through 8. This relative sizing can thus allow for at least some compression of the flexible rib member 145. In some embodiments, the flexible member 145 is electrically-conductive. In such embodiments, the compression of the flexible member 145 can preferably produce sufficient contact pressure effective for establishing at least a certain level (e.g., minimal level in some embodiments, etc.) of electrical conductivity between at least one conductive surface (e.g., ground traces, etc.) on the second side 184 of the board 180 and the second cover 140 via the flexible member 145.

The second cover 140 and flexible rib member 145 cooperatively define or form partitioned EMI shielding areas, enclosures, or compartments. When the assembly 100 is installed, the flexible or elastomer rib member 145 may intervene between one or more areas on a circuit board to partition one or more areas from other areas. The elastomer rib member 145 can provide for an attenuation of transfer of electromagnetic (EMI) energy between each of the one or more partitioned areas.

In the particular illustrated embodiment, the second cover 140 and rib member 145 cooperatively define two EMI shielding compartments 146 and 147.

Alternative embodiments can include more or less rib members in other configurations (e.g., shapes, sizes, materials, orientation, etc.) for defining more or less EMI shielding compartments. In yet other embodiments, the second cover does not include any of such rib members.

As shown in FIG. 8, the member 145 can be configured with a cross-section that reduces in width from a base portion (adjacent the second cover's inner surface 143) towards a free end portion. Alternative configurations can also be employed.

In some embodiments, the elastomer member 145 may comprise electrically-conductive material disposed on the exterior surface of the elastomer member. In such embodiments, the at least one electrically-conductive elastomeric member 145 can be disposed or affixed on the inner surface 143 of the second cover 140 by an adhesive (or other suitable attachment means) that bonds the electrically-conductive elastomeric member 145 to the second cover 140. The elastomer member 145 may be dispensed onto (e.g., via form-in-place dispensing equipment, hand-held dispenser or caulk gun, etc.), molded onto (e.g., overmolded, etc.) or attached (e.g., adhesively attached, etc.) to various portions of the second cover 140. By way of example only, various embodiments include electrically-conductive elastomer dispensed onto the second cover 140. Other embodiments include electrically-conductive elastomer over-molded onto the second cover 140 through an insert-molding process.

The electrically-conductive elastomeric member 145 can be formed from various materials. In some preferred embodiments, the member 145 is formed from elastomeric materials filled with electrically-conductive particles. Examples of preferred elastomeric materials include silicone, fluorosilicone, fluorocarbon, and Ethylene Propylene Diene Monomer [EPDM]. Thermoplastic elastomer can also be used as the elastomeric material. Examples of preferred electrically-conductive particles include silver coated glass particles, which can be used to make an elastomeric material electrically-conductive. In other embodiments, silver particles, silver coated copper particles, silver coated aluminum particles, silver plated nickel particles, nickel coated graphite particles, and graphite particles can also be used to make the elastomeric material electrically-conductive.

In some embodiments, the elastomer rib member 145 may be thermally conductive (e.g., have a thermal conductivity coefficient greater than that of air alone, etc.) for creating a thermally-conducting heat path from the assembly 100 to the board 180. In such embodiments, the elastomer rib member 145 may be configured to contact at least one electrically-conductive surface on the second side 184 of the board 180 from which to conduct heat, such as a grounding trace or a board-mounted electrical component. With this contact, the elastomer rib member 145 may facilitate transferring and/or thermally conducting of heat from the at least one electrically-conductive surface to the second cover 140.

In those embodiments in which the elastomeric rib member 145 is thermally conductive, a wide variety of materials can be used for such a thermal interface, which are preferably better thermal conductors and have higher thermal conductivities than air alone. Accordingly, the thermal interface (with its compressive contact against the electrical component) can thus allow for improved heat transfer from the electrical component to the second cover 140 as compared to those designs relying solely upon air to define the heat path between the electrical component and the underside of the cover. Some preferred embodiments include a thermal interface formed from T-flex™ 600 series thermal gap filler material commercially available from Laird Technologies, Inc. of Saint Louis, Mo. In one particular preferred embodiment, a thermal interface comprises T-fleX™ 620 thermal gap filer material, which generally includes reinforced boron nitride filled silicone elastomer. By way of further example, other embodiments include thermal interfaces molded from electrically-conductive elastomer. Additional exemplary embodiments include thermal interface materials formed from ceramic particles, ferrite EMI/RFI absorbing particles, metal or fiberglass meshes in a base of rubber, gel, grease or wax, etc. Other suitable thermal interface materials are set forth in the table below. Alternative embodiments, however, can provide an assembly that does not include any such thermal interfaces.

An exemplary process for assembling or installing the shielding assembly 100 to the board 180 is now provided for purposes of illustration only. In this example, the frame 160 is surface mounted (e.g., soldered, etc.) to the first side 182 of the board 180. The first and second covers 120, 140 are respectively positioned on, alongside, or adjacent the generally opposite first and second sides 182, 184 of the board 180, such that the first cover 120 is positioned generally over the frame 160 with the first cover's lid portion 121 substantially covering the frame's opening or window 168, and such that the first cover's protuberances 126 are interlockingly engaged within the second cover's openings 142. This interlocking engagement can also help retain the relative positioning of the first cover 120 generally over the frame 160.

During this exemplary installation process, the curved or bent end portions 128 of the tab end portions 127 operate as camming surfaces. As the first cover 120 is being disposed generally over the frame 160, contact between the camming surfaces 128 and the frame 160 (e.g., frame's perimeter rim 162, wall portions 164, etc.) and/or board 180 can urge the tabs 125 generally outwardly. Accordingly, this camming feature can thus facilitate the positioning of the tab end portions 127 through the corresponding notches 185 of the board 180 and subsequent engagement of the first cover's protuberances 126 within the second cover's openings 142.

Also during this exemplary installation process, the first cover's protuberances 126 can also operate as camming surfaces. As the first cover 120 is being disposed generally over the frame 160, contact between the protuberances 126 (e.g., the lower rounded portions of the inwardly extending half-dimples in the illustrated embodiment, etc.) and the frame 160 (e.g., frame's perimeter rim 162, wall portions 164, etc.) and/or board 180 can urge the tabs 125 generally outwardly. Accordingly, this camming feature can thus facilitate the positioning of the tab end portions 127 through the corresponding notches 185 of the board 180 and subsequent engagement of the first cover's protuberances 126 within the second cover's openings 142.

Depending on the particular application, the first cover 120 may be positioned adjacent the board's first side 182 and generally over the frame 160 before positioning the second cover 140 adjacent the board's second side 184. Or, for example, the second cover 140 may be positioned adjacent the board's second side 184 before positioning the first cover 120 adjacent the board's first side 182 and/or generally over the frame 160. In yet further embodiments, the relative positioning of first and second covers 120 and 140 may occur substantially simultaneously. In some embodiments, the positioning of the frame 160, first cover 120, and/or second cover 140 can be accomplished using pick-and-place equipment (e.g., vacuum pick-and-place equipment, etc.). In such embodiments, the frame 160, first cover 120, and/or the second cover 140 can be configured to allow for handling by pick-and-place equipment (e.g., vacuum pick-and-place equipment, etc.).

FIGS. 1 through 8 illustrate the frame 160, first cover 120, and second cover 140 according to a particular exemplary embodiment. Alternative embodiments can include a frame, a first cover, and/or a second cover having more or less than peripheral walls and/or peripheral walls in a different configuration (e.g., rectangular configurations, non-rectangular configurations, triangular, hexagonal, circular, other polygonal shapes, etc.) than what is shown in figures, etc. Further embodiments can include peripheral walls having more or less openings and/or protuberances than what are disclosed in the figures.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order or performance. It is also to be understood that additional or alternative steps may be employed.

The description of the disclosure is merely exemplary in nature and, thus, variations that do not depart from the gist of the disclosure are intended to be within the scope of the disclosure. Such variations are not to be regarded as a departure from the spirit and scope of the disclosure.

What is claimed is:

1. An assembly for providing EMI shielding for electrical components on generally opposite first and second sides of a board, the assembly comprising:
a frame attachable to the board's first side, the frame including walls and at least one opening along an upper portion of the frame, the frame's walls configured to be disposed generally about one or more electrical components on the board's first side;
a first cover configured to cover the at least one opening of the frame;
a second cover attachable to the first cover with the first and second covers respectively positioned along the board's generally opposite first and second sides;
whereby the assembly is operable for shielding one or more electrical components on the board's first side that are within a first interior defined by the frame's walls, first cover, and at least a portion of the board's first side, and one or more electrical components on the board's second side that are within a second interior defined by the second cover and at least a portion of the board's second side.

2. An electronic device including the assembly of claim 1, and a printed circuit board having electrical components on generally opposite first and second sides, and wherein the frame is attached to the board's first side, the first cover is disposed generally over the frame such that at least one electrical component on the board's first side is disposed within the first interior defined by the frame's walls, first cover, and at least a portion of the board's first side, and the second cover is attached to the first cover such that at least one electrical component on the board's second side is disposed within the second interior defined by the second cover and at least a portion of the board's second side.

3. The assembly of claim 1, wherein the assembly is configured such that the attachment of the second cover to the first cover also retains the positioning of the first cover relative to the frame.

4. The assembly of claim 1, wherein the second cover is removably attachable to the first cover.

5. The assembly of claim 1, wherein the assembly includes only one frame.

6. The assembly of claim 1, wherein the first cover includes a lid portion configured to cover the at least one opening of the frame, and tabs downwardly depending relative to the lid portion, the tabs having sufficient length for extending across a thickness defined between the board's first and second sides to thereby allow positioning of the end portions of the tabs on a side of the board opposite that of the lid portion.

7. The assembly of claim 6, wherein the end portions of the tabs include one or more protrusions configured for interlocking engagement with corresponding openings of the second cover.

8. The assembly of claim 6, wherein the end portions of the tabs are configured for positioning through corresponding holes in the board for engagement with the second cover.

9. The assembly of claim 6, wherein the end portions of the tabs are configured for positioning through corresponding notches defined along a periphery of the board for engagement with the second cover.

10. The assembly of claim 9, wherein the end portions of the tabs comprise inwardly extending half-dimples defining detents configured for interlocking engagement with corresponding openings of the second cover.

11. The assembly of claim 10, wherein the end portions of the tabs include camming surfaces for urging the tabs outwardly away from the frame thereby facilitating the positioning of the tabs through the corresponding notches generally around the board for interlockingly engaging the detents with the corresponding openings of the second cover.

12. The assembly of claim 1, wherein at least one of said first and second covers includes one or more protrusions for interlocking engagement with corresponding openings of the other one of said first and second covers to thereby attach the second cover to the first cover, and wherein the interlocking engagement of the one or more protrusions within the corresponding openings also retains the positioning of the first cover relative to the frame.

13. The assembly of claim 1, further comprising a plurality of interior EMI shielding compartments within at least one of said first and second interiors.

14. The assembly of claim 13, further comprising one or more electrically-conductive elastomeric members disposed along at least a portion of at least one of said first and second covers for defining at least a portion of at least one of said interior EMI shielding compartments.

15. The assembly of claim 1, further comprising at least one thermal interface material disposed on an interior portion of at least one of said first and second covers for forming a thermally-conducting heat path from one or more electrical components of the board to the assembly.

16. The assembly of claim 1, further comprising at least one resilient member disposed on an inner side of the first cover's lid portion, and wherein the frame includes at least one cutout portion configured to provide sufficient clearance for the at least one resilient member to thereby allow the first cover to be disposed generally over the frame without interfering contact between the at least one resilient member and the frame.

17. The assembly of claim 1, wherein at least one of said first and second covers comprises sheet metal.

18. A low-profile assembly for providing board-level EMI shielding for electrical components on generally opposite first and second sides of a board, the assembly comprising:
a frame attachable to the board's first side, the frame including walls and at least one opening along an upper portion of the frame, the frame's walls configured to be disposed generally about one or more electrical components on the board's first side;
a first cover having a lid portion to cover the at least one opening of the frame, and wall portions downwardly depending relative to the lid portion with sufficient length for extending across a thickness defined between the board's first and second sides to thereby allow positioning of the end portions of the first cover's wall portions on a side of the board opposite that of the lid portion,
a second cover;
at least one of said first and second covers including one or more protrusions for interlocking engagement with corresponding openings of the other one of said first and second covers to thereby attach the second cover to the first cover, the interlocking engagement of the one or more protrusions with the corresponding openings also retaining the relative positioning of the first cover generally over the frame with the lid portion covering the at least one opening of the frame;
whereby the assembly is operable for shielding one or more electrical components on the board's first side that are within a first interior defined by the frame's walls, first cover, and at least a portion of the board's first side, and one or more electrical components on the board's second side that are within a second interior defined by the second cover and at least a portion of the board's second side.

19. The assembly of claim 18, wherein the end portions of the first cover's wall portions comprise detents configured for interlocking engagement with corresponding openings of the second cover.

20. The assembly of claim 18, wherein the end portions of the first cover's wall portions are configured for positioning through corresponding openings of the board for engagement with the second cover.

21. The assembly of claim 18, further comprising a plurality of interior EMI shielding compartments within at least one of said first and second interiors.

22. The assembly of claim 21, further comprising one or more electrically-conductive elastomeric members disposed along at least a portion of at least one of said first and second covers for defining at least a portion of at least one of said interior EMI shielding compartments.

23. The assembly of claim 18, further comprising at least one resilient member disposed on an inner side of the first cover's lid portion, and wherein the frame includes at least one cutout portion configured to provide sufficient clearance for the at least one resilient member to thereby allow the first cover to be disposed generally over the frame without interfering contact between the at least one resilient member and the frame.

24. A method of providing EMI shielding for electrical components on generally opposite first and second sides of a board, the method comprising:
positioning a first cover relative to a frame such that one or more electrical components on the board's first side are within a first interior defined by the frame, first cover, and at least a portion of the board's first side; and
attaching a second cover to the first cover such that the first and second covers are respectively positioned along the board's generally opposite first and second sides, and such that one or more electrical components on the board's second side are within a second interior defined by the second cover and at least a portion of the board's second side.

25. The method of claim 24, further comprising attaching the frame to the board's first side.

26. The method of claim 24, wherein attaching the second cover to the first cover includes interlockingly engaging one or more protrusions of at least one of said first and second covers with corresponding openings of the other one of said first and second covers.

27. The method of claim 26, wherein the interlocking engagement of the one or more protrusions with the corresponding openings also retains the relative positioning of the first cover to the frame.

28. The method of claim 24, wherein the first cover includes a lid portion configured to cover the at least one opening of the frame, and tabs downwardly depending relative to the lid portion, and wherein the method includes covering the at least one opening of the frame with the lid portion, and positioning the first cover relative to the board such that end portions of the tabs are on a side of the board opposite that of the lid portion.

29. The method of claim 28, wherein attaching the second cover to the first cover includes interlockingly engaging one or more protrusions of the tabs with corresponding openings of the second cover.

30. The method of claim 28, wherein positioning the first cover relative to the board includes positioning the end portions of the tabs through corresponding openings in the board.

31. The method of claim 28, further comprising detaching the second cover from the first cover to access one or more electrical components on the board's second side.

32. The method of claim 31, further comprising reusing the removed second cover, or using a replacement second cover.

33. The method of claim 31, further comprising, after detaching the second cover from the first cover, moving the first cover relative to the frame to uncover the at least one opening of the frame to thereby allow access to one or more electrical components on the board's first side through the at least one opening of the frame.

34. The method of claim 33, further comprising reusing the removed first cover, or using a replacement first cover.
